(19) United States
(12) Patent Application Publication
(10) Pub. No.: US 2024/0296095 A1
(43) Pub. Date: Sep. 5, 2024

(54) APPARATUSES AND METHODS FOR READ COMMANDS WITH DIFFERENT LEVELS OF ECC CAPABILITY

(71) Applicant: Micron Technology, Inc., Boise, ID (US)

(72) Inventor: Sujeet Ayyapureddi, Boise, ID (US)

(73) Assignee: Micron Technology, Inc., Boise, ID (US)

(21) Appl. No.: 18/588,402

(22) Filed: Feb. 27, 2024

Related U.S. Application Data
(60) Provisional application No. 63/487,674, filed on Mar. 1, 2023.

(51) Int. Cl. G06F 11/10

(52) U.S. Cl. CPC G06F 11/1076

(57) ABSTRACT

Apparatuses, systems, and methods for read commands with different levels of error correction code (ECC) capability. A memory receives a first type of read command and reads data with a first level of ECC and receives a second type of read command and reads the data with a second level of ECC. For example, single error correction (SEC) may be used as part of the first type of read command and more errors may be detected/corrected as part of the second type of read command. A controller may read data using the first type of read command and if a signal is received indicating that an error was detected may read the data again using the second type of read command.

### CROSS REFERENCE TO RELATED APPLICATION(S)

This application claims the benefit under 35 U.S.C. § 119 of the earlier filing date of U.S. Provisional Application Ser. No. 63/487,674 filed Mar. 1, 2023 the entire contents of which are hereby incorporated by reference in their entirety for any purpose.

### BACKGROUND

This disclosure relates generally to semiconductor devices, and more specifically to semiconductor memory devices. In particular, the disclosure relates to volatile memory, such as dynamic random access memory (DRAM). Information may be stored on individual memory cells of the memory as a physical signal (e.g., a charge on a capacitive element). During an access operation, an access command may be received along with address information which specifies which memory cells should be accessed.

Some memories may include on-device error correction. In such devices, the memory array may generate parity bits when data is written to the array, and then during a read using that parity to check the data for errors. The number of errors which can be detected and/or corrected may be based, in part on the number of parity bits. Retrieving additional parity bits may increase a latency of the read operation, which may be undesirable.

### BRIEF DESCRIPTION OF THE DRAWINGS

FIG. 1 is a block diagram of a semiconductor device according an embodiment of the disclosure.

FIG. 2 is a block diagram of a memory device according to some embodiments of the present disclosure.

FIG. 3 is a block diagram of a write operation according to some embodiments of the present disclosure.

FIG. 4 is a block diagram of a first type of read operation according to some embodiments of the present disclosure.

FIG. 5 is a block diagram of a second type of read operation according to some embodiments of the present disclosure.

FIG. 6 is a block diagram of a write operation according to some embodiments of the present disclosure.

FIG. 7 is a block diagram of the second type of read operation according to some embodiments of the present disclosure.

FIG. 8 is a flow chart of a method of writing data to memory device according to some embodiments of the present disclosure.

FIG. 9 is a flow chart of a method of performing a read operation according to some embodiments of the present disclosure.

FIG. 10 is a method of reading data from a memory device according to some embodiments of the present disclosure.

### DETAILED DESCRIPTION

The following description of certain embodiments is merely exemplary in nature and is in no way intended to limit the scope of the disclosure or its applications or uses. In the following detailed description of embodiments of the present systems and methods, reference is made to the accompanying drawings which form a part thereof, and which are shown by way of illustration specific embodiments in which the described systems and methods may be practiced. These embodiments are described in sufficient detail to enable those skilled in the art to practice presently disclosed systems and methods, and it is to be understood that other embodiments may be utilized and that structural and logical changes may be made without departing from the spirit and scope of the disclosure. Moreover, for the purpose of clarity, detailed descriptions of certain features will not be discussed when they would be apparent to those with skill in the art so as not to obscure the description of embodiments of the disclosure. The following detailed description is therefore not to be taken in a limiting sense, and the scope of the disclosure is defined only by the appended claims.

Memory arrays may generally include a number of memory cells arranged at the intersection of word lines (rows) and bit lines/digit lines (columns). The columns may be grouped together into column planes, and a column select (CS) signal may be used to select a set of columns within each of the active column planes to provide data. During a write operation, the device receives data, and an error correction code (ECC) engine generates parity bits based on the data. The data and parity is then written to a word line specified by a row address and to bit lines selected by a column address. During a read operation, the data and parity are read out to the ECC engine, which uses the data and parity to determine if there are errors and/or locate and correct one or more errors in the data. The corrected data is then output from the device.

Memories will generally include a set of data column planes which are used to store data, and an extra column plane which is used to store parity bits. The error correction scheme which is implemented may thus partly depend on how many bits of parity are stored in the extra column plane. For example, a memory may generally read/write 8 bits at a time from each column plane, and so there may be 8 parity bits associated with the data (e.g., from 16 data column planes for 128 bits of data) which may allow the ECC engine to perform single error correction (SEC). However, if there are multiple errors, an ECC engine which implements SEC may incorrectly change one or more bits or otherwise fail to correct or even increase the number of errors. Additional error correction/detection is possible with increased numbers of parity bits, but memory architectures may be set up such that a maximum of a default amount of parity bits (e.g., 8 bits) may be accessed at the same time as the data. To increase the ECC capability, an additional access pass may be required, which may increase the latency. However, since memory devices generally receive many more read commands than write commands, the increase in latency may generally be a problem if it occurs as part of every read command.

The present disclosure is drawn to apparatuses, systems, and methods for read commands with different levels of ECC capability. A memory device may receive a write command and generate a number of parity bits. The parity bits may include a default number of parity bits and a number of extra parity bits. The memory device may use two access passes to write the parity bits to the memory array. The memory device may receive a first type of read command, and responsive to the first type of read command may read the data and the default number of parity bits. An ECC circuit may determine errors based on the data and the default number of parity bits. For example responsive to the first type of read command the ECC circuit may perform a first level of ECC such as single error correction (SEC).

The memory device may receive a second type of read command, and responsive to the second type of read command may perform two access passes, one to read the data and the default parity and one to read the extra parity. The ECC circuit may determine errors based on the data and the default and extra parity bits. Due to the increased amount of parity, an increased number of errors may be detected/corrected by the ECC circuit. For example, responsive to the first type of read command the ECC circuit may perform SEC, and responsive to the second type of read command the ECC circuit may perform a second level of ECC such as single error correction double error detection (SECDED), double error correction (DEC), triple error correction (TEC) or other forms of multi-bit error detection and/or correction.

A controller of the memory may determine when to perform the first type of read operation and when to perform the second type of read operation. For example, the controller may generally perform the first type of read operation. If the controller receives a signal from the memory indicating that an error was detected in the read data, then the controller may issue the second type of read command on the same data (e.g., the same memory address) for increased detection/correction capability.

In some embodiments, a single ECC circuit may be used which can selectively toggle between processing the default amount of parity bits or the default amount of bits plus the extra parity bits. For example an ECC engine may accommodate both SEC based on default amount of parity bits or SECDED based on the default plus the extra parity bits. In some embodiments, multiple ECC engines may be used, one for the first type of read operation, and one for the second type of read operation. For example, both ECC engines may separately generate a respective first and second plurality of parity bits during a write operation, where the second plurality has a greater number of bits than the first. During the first type of read operation the first plurality of parity bits may be read and used by the first ECC engine. During the second type of read operation the second plurality of parity bits may be read and used by the second ECC engine. The second ECC engine may implement a higher number of bits detected/corrected than the first.

As used herein, the term data may represent any bits of information that the controller wishes to store and/or retrieve from the memory. The term metadata may represent any bits of information about the data which the controller writes to and/or receives from the memory. For example, the metadata may be information that the controller generates about the data, about how or where the data is stored in the memory, about how many errors have been detected in the data, etc. The data and the metadata together represent information written to the memory by a controller and then also read from the memory by the controller, with the data and metadata differing in content and how they are generated in that the metadata is based on information about the data. The term parity may represent any bits generated by an error correction circuit of the memory based on the data, metadata, or combinations thereof. The parity may generally stay within the memory. In some embodiments, the amount of data and/or metadata retrieved as part of a single access operation may represent a set of bits which are a fragment of a larger piece of information. For example, the metadata bits retrieved as part of a single access operation (e.g., 4 bits) may not have any meaning on their own, but may have meaning when combined with sets of metadata bits retrieved as part of other access operations (e.g., to other memory arrays and/or to the same array at different times).

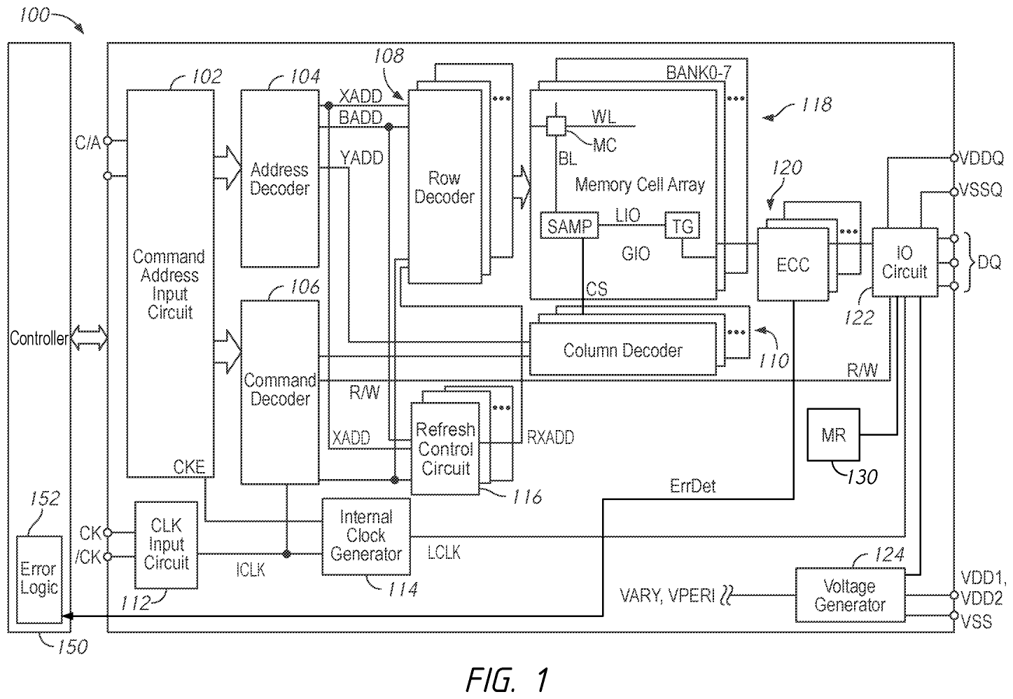

FIG. 1 is a block diagram of a semiconductor device according an embodiment of the disclosure. The semiconductor device 100 may be a semiconductor memory device, such as a DRAM device integrated on a single semiconductor chip. The device may be operated by a controller 150, such as a processor.

The semiconductor device 100 includes a memory array 118. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit lines BL. The selection of the word line WL is performed by a row decoder 108 and the selection of the bit lines BL is performed by a column decoder 110. In the embodiment of FIG. 1, the row decoder 108 includes a respective row decoder for each memory bank and the column decoder 110 includes a respective column decoder for each memory bank.

The bit lines BL are coupled to a respective sense amplifier (SAMP). Read data from the bit line BL is amplified by the sense amplifier SAMP, and transferred to an ECC circuit 120 over local data lines (LIO), transfer gate (TG), and global data lines (GIO). Conversely, write data outputted from the ECC circuit 120 is transferred to the sense amplifier SAMP over the complementary main data lines GIO, the transfer gate TG, and the complementary local data lines LIO, and written in the memory cell MC coupled to the bit line BL.

The semiconductor device 100 may employ a plurality of external terminals, such as solder pads, that include command and address (C/A) terminals coupled to a command and address bus to receive commands and addresses, clock terminals to receive clocks CK and/CK, data terminals DQ coupled to a data bus to provide data, and power supply terminals to receive power supply potentials VDD, VSS, VDDQ, and VSSQ.

The clock terminals are supplied with external clocks CK and/CK that are provided to an input circuit 112. The external clocks may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to the input/output circuit 122 to time operation of circuits included in the input/output circuit 122, for example, to data receivers to time the receipt of write data. The input/output circuit 122 may include a number of interface connections, each of which may be couplable to one of the DQ pads (e.g., the solder pads which may act as external connections to the device 100).

The C/A terminals may be supplied with memory addresses. The memory addresses supplied to the C/A terminals are transferred, via a command/address input circuit 102, to an address decoder 104. The address decoder 104 receives the address and supplies a decoded row address XADD to the row decoder 108 and supplies a decoded column address YADD to the column decoder 110. The decoded row address XADD may be used to determine which row should be opened, which may cause the data along the bit lines to be read out along the bit lines. The column decoder 110 may provide a column select signal CS, which may be used to determine which sense amplifiers provide data to the LIO. The address decoder 104 may also supply a decoded bank address BADD, which may indicate the bank of the memory array 118 containing the decoded row address XADD and column address YADD.

The C/A terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to a command decoder 106 via the command/address input circuit 102. The command decoder 106 includes circuits to decode the internal command signals to generate various internal signals and commands for performing operations. For example, the command decoder 106 may provide signals which indicate if data is to be read, written, etc.

The memory includes a mode register 130 which may be used to control various aspects of the memory 100. For example, the mode register 130 may include one or more setting registers which specify various settings of the memory. The controller 150 may perform a mode register write operation to set values of one or more setting registers. The controller 150 may perform a mode register read operation to check the value of various registers, which may contain information about various settings, conditions of the memory (e.g., temperature), error reports (e.g., error check and scrub information), other information, or combinations thereof. In some embodiments, the mode register 130 may be used to enable the operation of the extra parity bits as described herein. In some embodiments, the mode register 130 may also set various properties such as how many extra parity bits are used. In some embodiments, the mode register 130 may enable metadata, which may be stored in a manner similar to the extra parity, but which is provided by the controller 150 rather than generated by the ECC circuit 120.

The device 100 may receive an access command which is a write command. When the write command is received, and a bank address, a row address and a column address are timely supplied with the write command by the controller 150, write data supplied to the data terminals DQ by the controller 150 are provided along the data bus and written to a memory cells in the memory array 118 corresponding to the row address and column address. The write command is received by the command decoder 106, which provides internal commands so that the write data along with any additional information (e.g., metadata and/or additional parity) is received by data receivers in the input/output circuit 122. The ECC circuit 120 generates number of parity bits based on the received data and the data and parity are provided by the ECC circuit 120 to the memory array 118 to be written into the memory cells MC which are specified by the row and column address.

The ECC circuit 120 may generate a number of parity bits which includes a default number of parity bits and an extra number of parity bits. For example, the default number of parity bits (e.g., 8 parity bits) may be associated with a first type of ECC operation (e.g., SEC) and the default+the extra parity may be associated with a second type of ECC operation (e.g., SECDED). In some embodiments, there may be two separate ECC circuits, and the first ECC circuit may provide the default parity bits (e.g., 8 parity bits) associated with a first type of ECC operation, and the second ECC circuit may provide extra parity bits (e.g., 9, 10, 11, 12, etc. extra parity bits) which are separately associated with a second type of ECC operation. The default bits may be written to the memory array 118 as part of a first access operation along with the data, and the extra parity bits may be written to a different location as part of a second access operation.

The device 100 may receive an access command which is a read command. The read command may be a first type or a second type. For example, the controller 150 may provide an extra bit which specifies which type of read command is being sent. When a read command is received, and a bank address, a row address and a column address are timely supplied with the read command by the controller 150, read data is read from memory cells in the memory array 118 corresponding to the row address and column address. The read command is received by the command decoder 106, which provides internal commands so that read data and read parity bits from the memory array 118 is provided to the ECC circuit 120. The ECC circuit receives the data and the parity bits from the array and detects and/or corrects errors in the data. The correct read data is provided along the data bus and output to outside from the data terminals DQ via the input/output circuit 122.

If the read command is the first type of read command, then the data and default parity may be read out as part of a single access pass. For example, 8 parity bits and 128 data bits may be read out to the ECC circuit 120, which may perform an ECC operation (e.g., SEC) based on that information. If an error is detected and/or corrected, the memory 100 may provide a signal ErrDet to the controller indicating that an error was detected. For example, the signal ErrDet may be provided directly to the controller (e.g., via the DQ pins) or may be indirectly provided (e.g., as part of a sideband communication to tell the controller to check error registers of the mode register 130, one of which may include the signal ErrDet).

If the read command is the second type of read command, then the data and the extra parity (potentially along with the default parity depending on the embodiment) may be read out using two access passes. For example, a first access may read out the extra parity from the memory array 118, and a second access pass may read out the data (and the default parity). The data and the extra parity (which may be joined with the default parity in some embodiments) are provided to the ECC circuit 120, which performs error correction (e.g., SECDED, DEC, TEC, etc.). If an error is corrected and/or detected, the memory 100 may provide a signal ErrDet to the controller 150 indicating that an error was detected (either directly or indirectly), potentially along with additional information such as how many errors were detected.

The use of the additional or extra parity bits may allow for an increased protection of the data in the second type of read operation compared to the first type of read operation. For example, the first type of read operation may retrieve 128 data bits, along with 8 default parity bits. Using this combination, the ECC circuit 120 may implement a single error correction (SEC) scheme, where up to one bit of error is located and corrected. However, when the second type of read operation is performed, then the 128 data bits is read out from the same location along with more than 8 parity bits (e.g., the default 8 plus 1, 2, 3 etc. extra parity bits or 9, 10, 11, 12, etc extra parity bits), which may enable a single error correction, double error detection (SECDED), double error correction (DEC), triple error correction (TEC) and/or other error correction schemes.

The controller 150 may determine whether to perform the first or the second type of read command. For example, the read command may include a bit which may specify the type of read command. The controller 150 may generally perform the first type of read command. The controller 150 may use internal logic to determine when the second type of read command should be used instead. For example, the controller 150 may include error logic 152. The controller may provide the first type of read command along with a row and column address and receive data from the memory 100. The error logic 152 may receive a signal from the memory 100 which indicates that an error was detected in the read data. Responsive to that, the error logic 152 may instruct the controller 150 to perform the second type of read command on the same row and column address, in order to have the data examined at a higher form of ECC than SEC. Since SEC may introduce new errors if more than one bit of error is present, the use of higher ECC may allow for the correct data to still be recovered (at the cost of reserving storage space for extra ECC and additional latency for write operations).

The device 100 includes refresh control circuits 116 each associated with a bank of the memory array 118. Each refresh control circuit 116 may determine when to perform a refresh operation on the associated bank. The refresh control circuit 116 provides a refresh address RXADD (along with one or more refresh signals, not shown in FIG. 1). The row decoder 108 performs a refresh operation on one or more word lines associated with RXADD. The refresh control circuit 116 may perform multiple types of refresh operation, which may determine how the address RXADD is generated, as well as other details such as how many word lines are associated with the address RXADD.

The power supply terminals are supplied with power supply potentials VDD and VSS. The power supply potentials VDD and VSS are supplied to an internal voltage generator circuit 124. The internal voltage generator circuit 124 generates various internal potentials VARY, and the like based on the power supply potentials VDD and VSS supplied to the power supply terminals.

The power supply terminals are also supplied with power supply potentials VDDQ and VSSQ. The power supply potentials VDDQ and VSSQ are supplied to the input/output circuit 122. The power supply potentials VDDQ and VSSQ supplied to the power supply terminals may be the same potentials as the power supply potentials VDD and VSS supplied to the power supply terminals in an embodiment of the disclosure. The power supply potentials VDDQ and VSSQ supplied to the power supply terminals may be different potentials from the power supply potentials VDD and VSS supplied to the power supply terminals in another embodiment of the disclosure. The power supply potentials VDDQ and VSSQ supplied to the power supply terminals are used for the input/output circuit 122 so that power supply noise generated by the input/output circuit 122 does not propagate to the other circuit blocks.

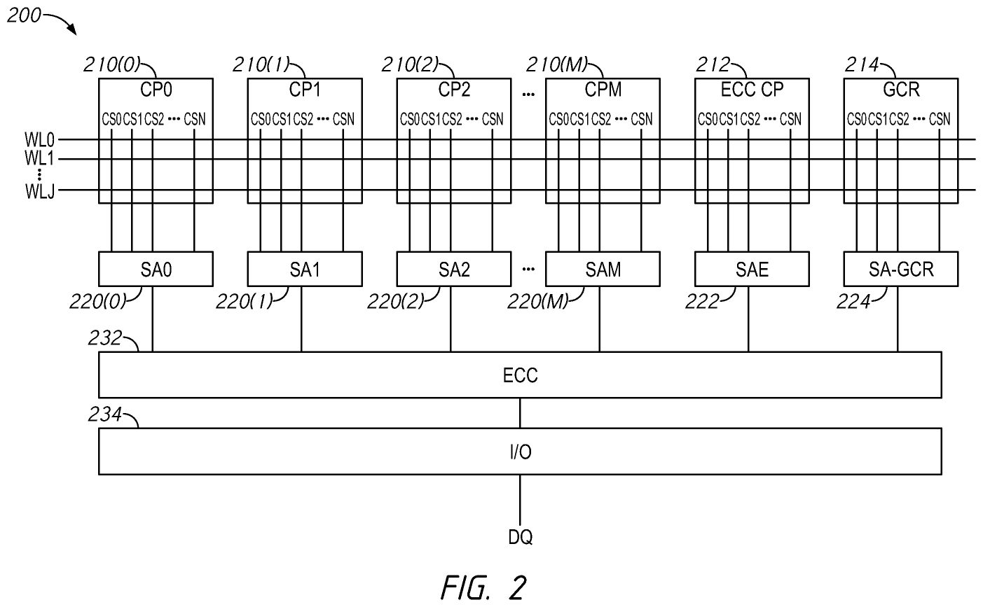

FIG. 2 is a block diagram of a memory device according to some embodiments of the present disclosure. The memory device 200 may, in some embodiments, represent a portion of the memory device 100 of FIG. 1. The view of FIG. 2 shows a portion of a memory array 210-214 and 220-224 which may be part of a memory bank (e.g., 118 of FIG. 1) along with selected circuits used in the data path such as the ECC circuit 232 (e.g., 120 of FIG. 1) and IO circuits 234 (e.g., 122 of FIG. 1). For clarity certain circuits and signals have been omitted from the view of FIG. 2.

The memory device 200 is organized into a number of column planes 210-214. Each of the column planes represents a portion of a memory bank. Each column plane 210-214 includes a number of memory cells at the intersection of word lines WL and bit lines. The word lines may be extend across multiple of the column planes 210-214. The bit lines may be grouped together into sets which are activated by a column select signal CS provided by a column decoder (e.g., 110 of FIG. 1).

For the sake of clarity, only a single vertical line is used to represent the bit lines of each column select set in a given column plane, however, there may be multiple bit lines accessed by each CS value in each column plane. For example, each vertical line may represent 8 bit lines, all accessed in common by a value of CS. As used herein, a ‘value’ of CS may refer to a decoded signal provided to sets of bit lines. So a first value may represent a first value of a multibit CS signal, or after decoding a separate binary signal (e.g., a signal line being active). For example, if the (pre-decoded) CS signal is 6 bit signal (e.g., with 64 values), then there may be 64 different decoded CS signals.

The memory 200 includes a set of data column planes 210 as well as an extra column plane or ECC column plane 212. The extra column plane 212 may be used to store the default parity bits. In some embodiments, the memory 200 may also include an optional global column redundancy (GCR) column plane 214. In some embodiments, the GCR plane 214 may have fewer memory cell (e.g., fewer column select groups) than the data column planes 210. The GCR CP 214 includes a number of redundant columns which may be used as part of a repair operation. For example, if a value of the CS signal is identified as including defective memory cells in one of the data column planes 210, then the memory may be remapped such that the information which would have been stored in that column plane for that value of CS is instead stored in the GCR CP 214.

An example memory device 200 according to some embodiments of the present disclosure may include 16 data column planes 210(0)-210 (15). Each of those data column planes 210 includes 64 sets of bit lines (e.g., CS sets) activated by a value of the column select signal, and each set of bit lines includes 8 bit lines. Accordingly, when a word line is opened responsive to a row address, and a column select signal is provided to each of the 16 column planes then 8 bits are accessed from each of the 16 column planes for a total of 128 bits. The column select signal is also provided to the ECC CP 212, which accesses an additional 8 bits of default parity associated with the 128 bits. If a repair has been performed, the GCR CP 214 may also be accessed and the information accessed in the GCR CP 214 may be swapped for the information accessed from the repaired CP (e.g., by multiplexing a GCR local input/output line onto the repaired LIO line). Accordingly, the maximum number of bits that can be retrieved as part of an access pass in the example memory device is 128 bits from the data column planes 210 (with 8 bits substituted from the GCR CP 214 if there has been a repair) along with 8 additional bits from the extra CP 212. For the sake of consistency, reference will generally be made throughout to these example values, however, it should be understood that embodiments of the present disclosure may have a different architecture, which involves more or fewer column planes, more or fewer bit lines per CS set, more or fewer, CS sets per column plane, and so forth.

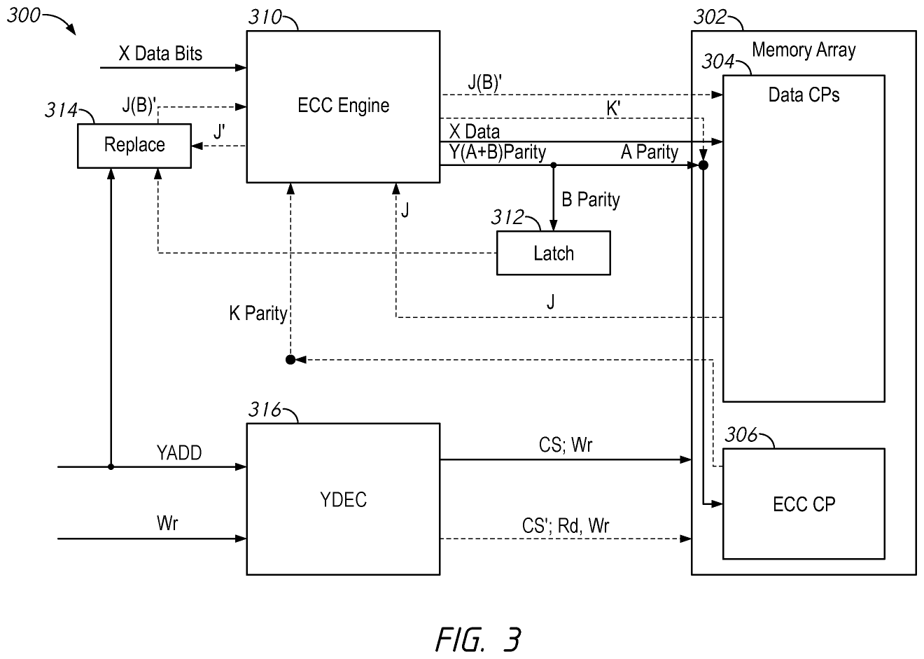

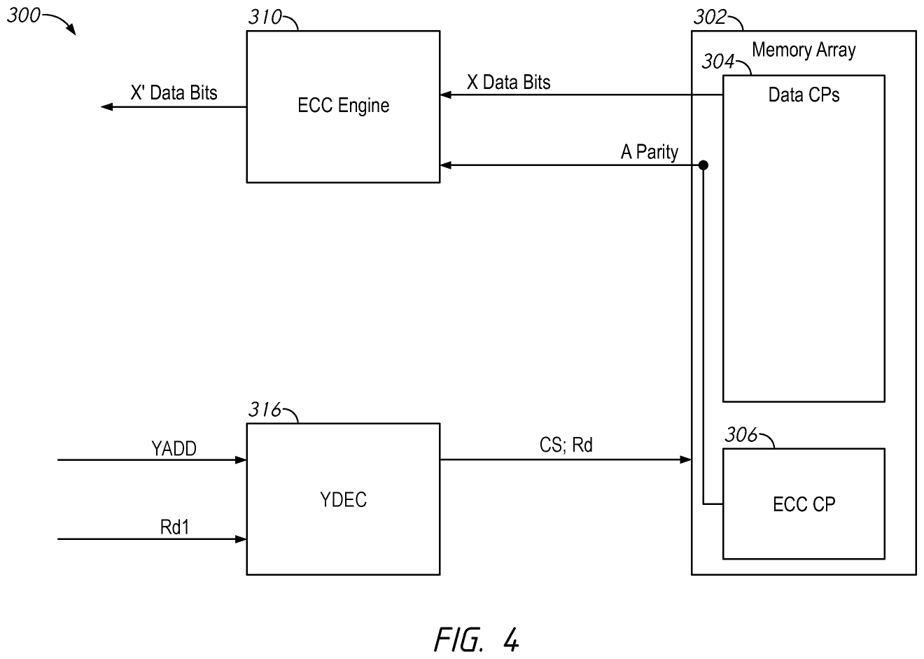

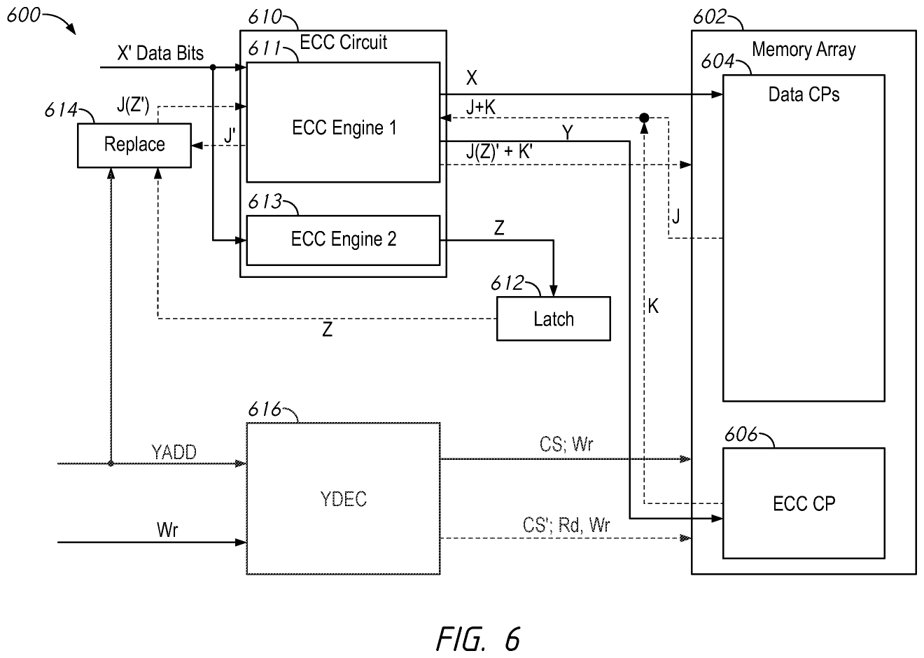

When the first type of read operation is performed, then a single-pass access operation is performed where the row decoder may activate a word line (based on a received row address) and the column decoder activates a CS set in each CP 210 and 212 (and 214 if a repair has been performed) based on the received column address. When a write operation or the second type of read operation is performed, then a two-pass operation may be performed, where two access passes are performed, one of which accesses the memory cells which store the data and the default parity, and one of which accesses a codeword of additional information which includes the additional information (e.g., metadata and extra parity) associated with the data. Example write operations are described in more detail in FIGS. 3 and 6. Example read operations are described in more detail in FIGS. 4-5 and 7.

During a write operation or the second type of read operation, the column decoder may generate two CS signals for each access operation (e.g., responsive to a received column address), one for the first access pass and one for the second access pass. In some embodiments, the same word line may be used for both access passes (e.g., both the data and its associated information may be stored in memory cells along a same word line). The codeword of additional information may include additional information associated with multiple data codewords (e.g., sets of 128 bits of data) along the row. The additional information may include the extra parity and in some embodiments also metadata about the associated data. Depending on how many bits of additional information are enabled, there may be multiple codewords of additional information along each row. Each codeword of additional information is stored in the data column planes 210, and each codeword of additional information, similar to the data codewords, has associated parity stored in the ECC CP 212.

In an example embodiment, if there are 4 additional bits of information (e.g., 2 bits of metadata and two extra parity bits) enabled for each data codeword, and there are 16 column planes, each with 64 CS sets, each containing 8 bit lines, then data may be stored in CS0-CS61 of the data column planes 210, while additional information is stored in CS62-63 of the data column planes. The codewords of additional information may also have associated parity bits (e.g., a default number of parity bits) which may be stored in CS62-63 of the ECC CP 212. When a column address is received, during an access pass to access the data, the column decoder may provide a CS signal in the range of CS0-CS61, and during an access pass to access the additional information, the column decoder may provide a CS signal in the range of CS62-63. Other arrangements of data and additional information may be used in other example embodiments.

As described in more detail herein, the additional information may include extra parity bits. The extra parity bits may increase an amount of protection offered by the ECC circuit 232 when the second type of read operation is performed. For example, if the default amount of parity (e.g., 8 bits of parity for every 128 bits of data) enables SEC, then when extra parity is enabled, the ECC circuit 232 may perform SECDED on the data.

In some embodiments, a single ECC circuit may be used for both types of read operation. Accordingly, the ECC circuit 232 may have optional components which are not enabled when the default number of parity bits are used, but which are enabled when extra parity is used. For example, the ECC circuit 232 may include a logic tree which combines inputs such as the data to generate parity bits. The logic tree may include a portion which generates extra parity bits and which is disabled when extra parity are not used. Similarly, the ECC circuit 232 may include additional inputs for the extra parity bits used during a read operation which are unused when extra parity bits are not enabled. FIGS. 3-5 describe an example embodiment with a single ECC circuit in more detail.

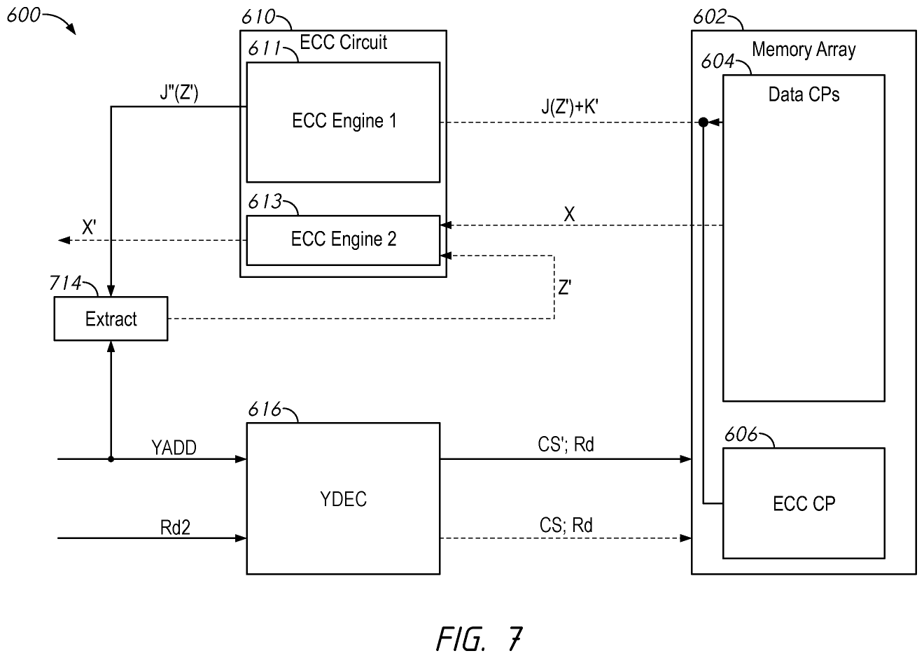

In some embodiments, two separate ECC circuits may be used, one for write operations and the first type of read operation and one for write operations and the second type of read operation. For example, during a write operation the first and the second ECC circuit may both receive the same data, and each separately generate parity bits. The first ECC circuit generates the default ECC parity bits, and the second ECC circuit generates the extra parity. In such an embodiment, the extra parity may ‘stand-alone’ rather than representing extra bits which only provide error correction when added to the default parity. Although in such an embodiment the extra parity may represent more total bits, it may still be written (and read) as part of a two pass access. FIGS. 6-7 describe an example embodiment where two ECC circuits are used in more detail.

The different read operations may have different amounts of latency. For example, there may be a long column-to-column delay time tCCD_L which indicates the minimum amount of time before two access passes can be performed on the same bank. The write operation and the second type of read operation may both incur two extra tCCD_L compared to the first type of read operation, since both involve a second access pass which is a read/modify/write cycle, as described in more detail herein. However, since the first type of read operation may be much more common than write operations or the second type of read operation, the overall increase in the devices latency may be less of an issue.

FIGS. 3-5 show block diagrams which represents example write and the first type and second type of read operations respectively. The figures represent a simplified view of the flow of information during a first and second access pass, both of which are performed responsive to a single access operation on the memory (e.g., both passes are responsive to the same addresses and command provided by the controller). In FIGS. 3-5, a solid line indicates a first access pass, while a dotted line indicates a second access pass. For the sake of brevity, since certain components of FIGS. 3-5 may generally be similar to each other, they may not be described in detail with respect to both Figures. Similarly, components between FIGS. 3-5 will generally be referenced with the same reference numbers, since the operations described in FIGS. 3-5 may be performed by the same hardware in some embodiments. FIGS. 3-5 represent an embodiment where a single ECC circuit is used, which generates a default set of parity bits used for SEC, and then extra parity bits which together with the default parity may be used for more error correction.

FIG. 3 is a block diagram of a write operation according to some embodiments of the present disclosure. The Figures shows a memory device 300, which in some embodiments may implement a portion of the memory device 100 of FIGS. 1 and/or 200 of FIG. 2. For example, the memory device 300 includes a memory array 302 (e.g., 118 of FIG. 1) which includes data column planes 304 (e.g., 210 of FIG. 2) and an ECC column plane 306 (e.g., 212 of FIG. 2). Also included are an ECC engine 310 (e.g., 120 of FIGS. 1 and/or 232 of FIG. 2) and a column decoder YDEC 316 (e.g., 110 of FIG. 1).

As part of the write operation, the memory receives (e.g., from a controller) X data bits (e.g., 128 data bits) along with a row and column address and a write command. The X data bits are provided to the ECC engine, which generates Y parity bits based on the X data bits. The Y parity bits include A default bits and B extra parity bits. For example, there may be X=128 data bits, which are used to generate 9 parity bits (e.g., A=8 and B=1).

The Y parity bits are split into two portions, a first portion including the default parity bits A, and a second portion including the B extra parity bits. The B extra parity bits are stored in latch 312.

As part of a first access pass, the column decoder 316 provides a first column select signal CS along with a write command Wr to the memory array. The X data bits are written to data column planes 304, and the first portion of the parity bits which includes the A default parity bits is written to the ECC column plane 306.

As part of a second access pass, the memory 300 performs a read/modify/write (RMW) operation on a codeword of additional information which will be modified to include the second portion of the parity bits including the B extra parity bits. As part of the RMW operation, the column decoder provides a second column select signal based on the column address YADD along with a read command. A codeword of additional information including J bits is read out from the data column planes 304, and K parity bits associated with the J additional information bits is read out from the ECC CP 306. In some embodiments, J may generally be equal to X, and K may generally be equal to A. For example, there may be J=128 additional information bits and K=8 parity bits associated with the additional information codeword.

The J additional information bits and K parity bits are read out to the ECC engine 310, which checks for errors in the J additional information bits based on the K parity bits. For example, the ECC engine 310 may perform SEC on the J additional information bits and provide corrected additional information J′. The corrected additional information J′ is provided to a logic circuit 314, which performs the modify part of the RMW operation. The logic circuit 314 replaces one or more bits of the corrected additional information J′ with the extra parity bits B stored in the latch 312. This may generate modified additional information J (B)′. For example, if B=1 bit, then one bit of the 128 bits of J′ may be replaced with the value of the extra parity bit B. The logic 314 may choose which bit of J′ to replace based on the column address (and/or a signal such as CS′ based on the column address).

As the write part of the RMW operation, the ECC engine 310 receives the modified additional information J (B)′ and generates updated parity K′ based on that modified additional information J (B)′. The column decoder then provides a write command Wr (along with the second CS signal CS′) to the memory array 302, and the modified additional information J (B)′ is written to the data column planes 304 and the updated parity K′ is written to the ECC CP 306. In this manner the first portion of the parity (the default parity bits A) is written to the ECC CP 306 and the second portion of the parity (the extra parity bits B) are written to the data CPs 304.

If metadata is enabled on top of the extra parity bits, then as part of the write operation, the memory 300 may receive M metadata bits along with the X data bits. The ECC engine 310 may generate the Y parity bits based on the X data bits and the M metadata bits, and then both the B extra parity bits and the M metadata bits may be stored in the latch 312. During the second access pass, the corrected additional information may be modified to include both the B parity bits and the M metadata bits.

FIG. 4 is a block diagram of a first type of read operation according to some embodiments of the present disclosure. FIG. 4 shows the memory device 300 of FIG. 3, but this time an example read operation is shown which is used to retrieve the information which was stored as part of the write operation described with respect to FIG. 3. For the sake of consistency, the same reference numbers are used as were used in FIG. 3, and details and descriptions already described with respect to FIG. 3 will not be repeated again for the sake of brevity.

The first type of read operation is a single-pass access operation since the data and the default parity bits, but not the extra parity bits, are accessed. The column decoder 316 receives a first type of read command Rd1 (e.g., from command decoder 106 of FIG. 1). The column decoder 316 receives the column address YADD and provides a column select signal CS along with a read command. Along a row (activated by a row decoder responsive to a row address), bit lines associated with the column select signal CS in the data column planes 304 and ECC CP 306 are activated. The X data bits are read out from the data CPs 304, and the A default parity bits are read out from the ECC CP 306. The ECC engine 310 detects and/or corrects errors based on the X data bits and A default parity bits. For example, the ECC engine 310 may perform SEC. The corrected data X′ is provided to the controller (e.g., 150 of FIG. 1).

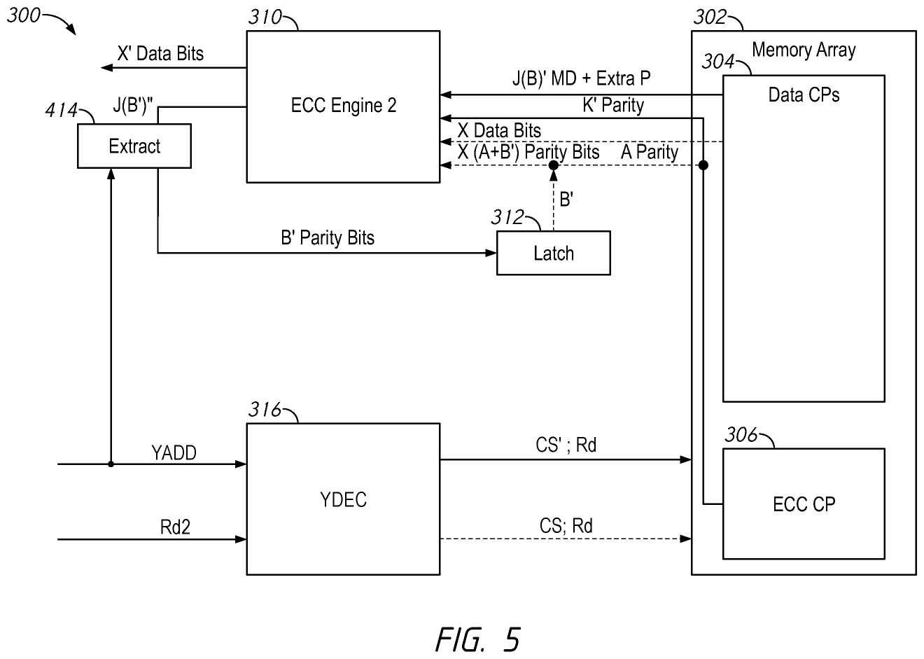

FIG. 5 is a block diagram of a second type of read operation according to some embodiments of the present disclosure. FIG. 5 shows the memory device 300 of FIG. 3, but this time an example second type of read operation is shown which is used to retrieve the information including the extra parity which was stored as part of the write operation described with respect to FIG. 3. For the sake of consistency, the same reference numbers are used as were used in FIG. 3, and details and descriptions already described with respect to FIG. 3 will not be repeated again for the sake of brevity.

As part of a read operation, the memory 300 receives a second type of read command Rd2 along with addresses including row and column addresses. Similar to the write operation described with respect to FIG. 3, a two-pass access may be performed. The first access pass is a read to retrieve the codeword of additional information J (B)′ which may be the modified codeword which includes the extra parity bits B. The column decoder provides the second column select signal CS′ along with a read command Rd. The modified codeword of additional information J (B)′ is read out from the data CPs 304 and the updated K′ parity bits associated therewith are read out from the ECC CP 306. The ECC engine corrects the J (B)′ bits based on the K′ parity bits (e.g., by performing SEC) to generate corrected modified additional information J (B′)″.

A logic circuit 414 extracts the corrected extra parity bits B′ from the corrected modified additional information J (B′)″. For example, the logic circuit 414 may use the row address, or one or more signals derived therefrom (e.g., CS′) to determine which bits of J(B′)″ are B′. In some embodiments, the logic circuit 414 may be the same as the logic circuit 314 of FIG. 3. The extracted corrected extra parity bits B′ are stored in latch 312,

As part of a second access pass, the column decoder 316 provides the first column select signal CS along with a read command. Responsive to this, the X data bits are read out from the data CPs 304 and the default A parity bits are read out from the ECC CP 306. The A parity bits are joined with the B′ parity bits stored in the latch 312 to reform the Y parity bits (e.g., A+B′). The ECC engine 310 receives the X data bits and the Y parity bits and detects and/or corrects errors based on that information. For example, the ECC engine 310 may perform SECDED on the data based on the parity Y. The ECC engine 310 provides corrected data X′, which is provided to the controller. In some embodiments, if the ECC engine 310 corrects an error and/or if the ECC engine detects an error it cannot correct (e.g., a double bit error), it will provide a signal indicating that an error was detected.

FIGS. 6-7 show an example embodiment where two separate ECC engines are used, one of which performs SEC for the first type of read operation and one of which performs a higher form of ECC such as SECDED, double error correction (DEC), triple error correction (TEC), etc. FIGS. 6-7 may generally be similar to FIGS. 3-5 and for the sake of brevity certain features and components already described with respect to FIGS. 3-5 will not be described again with respect to FIGS. 6-7. Similarly, the same reference numbers will generally be used for both FIGS. 6 and 7, as the same components may be used for both read and write operation.

FIG. 6 is a block diagram of a write operation according to some embodiments of the present disclosure. The write operation may be generally similar to the write operation of FIG. 3, but in the write operation of FIG. 6, an ECC circuit 610 with two ECC engines 611 and 613 is used, rather than a single ECC engine as in FIG. 3. The Figures shows a memory device 600, which in some embodiments may implement a portion the memory device 100 of FIGS. 1 and/or 200 of FIG. 2. For example, the memory device 600 includes a memory array 602 (e.g., 118 of FIG. 1) which includes data column planes 604 (e.g., 210 of FIG. 2) and an ECC column plane 606 (e.g., 212 of FIG. 2). Also included are an ECC circuit 610 (e.g., 120 of FIGS. 1 and/or 232 of FIG. 2) and a column decoder YDEC 616 (e.g., 110 of FIG. 1).

A controller (e.g., 150 of FIG. 1) provides a write command and a column address YADD. The column decoder 616 provides a first column select signal CS and a write command as part of first access pass. The controller also provides data bits X (e.g., 128 data bits) to the ECC circuit 610. The first ECC engine 611 generates default parity bits Y, and the second ECC engine 613 generates extra parity bits Z. The number of bits of Z may be greater than the number of bits of Y. For example, Y may be 8 bits, while Z may be 9, 10, 11, 12, or more bits. Unlike the embodiment of FIGS. 3-5, in the embodiment of FIGS. 6-7, the sets of parity bits Y and Z are independent of each other. In other words, the parity bits Y do not necessarily represent a subset of the bits of Z.

Responsive to the first column select signal CS and the write command Wr, the data bits X are written to the data column plane 604 and the default parity bits Y are written to the ECC column plane 606. The extra parity bits Z are stored in a latch 612.

As part of a second access operation, the column decoder provides a second column select signal CS′ and a read command followed by a write command. Responsive to CS′, a codeword of additional information J is read from the data column planes 604 and its associated parity K is read from ECC column planes 606. The number of bits in J and K may match the numbers of bits in X and Y respectively (e.g., 128 bits and 8 bits). The first ECC engine 611 may correct errors in the bits J based on J+K (e.g., by performing SEC on J) to generate a corrected codeword of addition information J′. A logic circuit 614 may insert the parity bits Z into the corrected codeword J′ to generate J′(Z). For example, the bits Z may overwrite the bits which were previously at that location. The logic circuit 614 may use the column address YADD (and/or a signal derived therefrom such as CS) to determine where in the codeword J′ to insert the bits Z.

The corrected codeword modified with the second set of parity bits J′(Z) is provided to the first ECC engine 611 which generates updated parity bits K′ based on the codeword J′(Z). Responsive to the second CS signal CS′ and the write signal Wr, the codeword J′(Z) is written to the data column planes 604 and the updated parity bits K′ are written to the ECC column plane 606.

FIG. 7 is a block diagram of the second type of read operation according to some embodiments of the present disclosure. FIG. 7 shows the memory device 600 of FIG. 6, but this time an example second type of read operation is shown which is used to retrieve the information including the extra parity which was stored as part of the write operation described with respect to FIG. 6. For the sake of consistency, the same reference numbers are used as were used in FIG. 6, and details and descriptions already described with respect to FIG. 6 will not be repeated again for the sake of brevity.

While not represented by a separate figure, the first type of read operation may be broadly similar to the first type of read operation described in FIG. 4, with the data X and the parity Y are provided to the first ECC engine 611.

As part of the second type of read operation, the controller (e.g., 150 of FIG. 1) provides a second type of read command Rd2 along with a column address YADD. Responsive to these commands, the column decoder provides the second column select signal CS′ along with a read command. Responsive to the second column select signal CS′ and the read command Rd, the codeword J′(Z) is read from the data column planes 604 and the associated parity K′ is read out from the ECC column plane 606. The first ECC engine 611 performs a first level of ECC (e.g., SEC) on the codeword J′(Z) based on the parity bits K′ to generate the corrected codeword J″ (Z′). Here the notation Z′ indicates that the parity bits Z have been corrected.

A logic circuit 714 extracts the bits Z′ from the codeword J″ (Z′). Which bits are extracted from the string of J″ is determined by the column address YADD (and/or one or more signals derived therefrom such as CS).

As part of a second access pass, the column decoder provides the first column select signal CS along with a read command Rd. Responsive to the read command and CS, the data bits X are read out from the data column plane 604 (the default parity Y may also be read out from the ECC CP 606, but is ignored in this read operation). The data bits are provided to the second ECC engine 613 along with the parity bits Z′. The second ECC engine 613 performs a second level (e.g., SECDED, DEC, TEC, etc.) of ECC on the bits X based on the parity bits Z′ and provides corrected data bits X′.

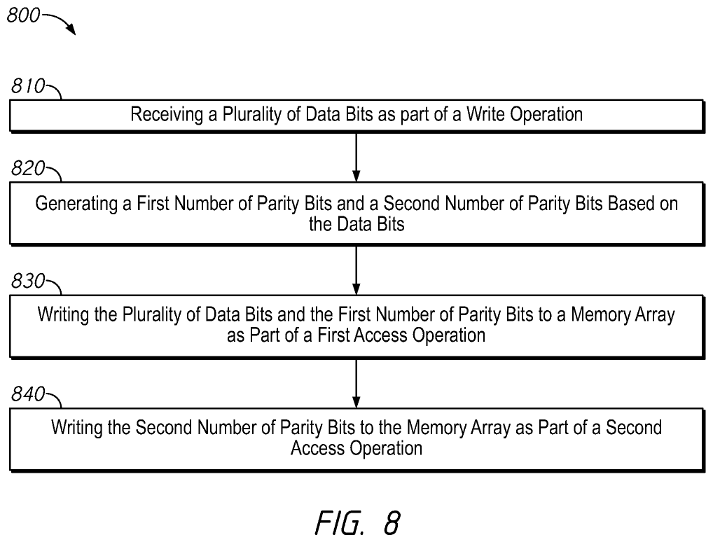

FIG. 8 is a flow chart of a method of writing data to memory device according to some embodiments of the present disclosure. The method 800 may, in some embodiments, be implemented by one or more of the apparatuses or systems described herein. For example, the method 800 may be implemented by the memory device 100 of FIG. 1, 200 of FIG. 2, 300 of FIGS. 3-5 and/or 600 of FIGS. 6-7.

The method 800 may generally begin with box 810, which describes receiving a plurality of data bits as part of a write operation. The data bits may be received from a controller (e.g., 150 of FIG. 1) along with a write command. The data may be received along with a row address and a column address.

Box 810 may generally be followed by box 820, which describes generating a first number of parity bits and a second number of parity bits based on the data bits. For example, the first number of parity bits may represent a default number of parity bits (e.g., Y in FIGS. 3-7). The method 800 may include generating the parity bits with an ECC circuit (e.g., 120 of FIGS. 1 and/or 232 of FIG. 2). In some embodiments, the method may include generating the first number of parity bits and the second number of parity bits with a same ECC engine (e.g., 310 of FIGS. 3-5). For example, the first number of parity bits may represent a default number of parity bits (e.g., 8 parity bits) and the extra parity bits may represent extra parity bits generated by the same ECC engine (e.g., 1, 2, 3, etc. extra parity bits). In some embodiments, the method 800 may include generating the first number of parity bits with a first ECC engine (e.g., 611 of FIGS. 6-7) and generating the second number of parity bits with a second ECC engine (e.g., 613 of FIGS. 6-7). For example, the first number of parity bits may represent a default number of parity bits (e.g., 8 parity bits) and the second number of parity bits may represent more parity bits (e.g., 9, 10, 11, 12, etc.).

Box 820 may generally be followed by box 830, which describes writing the plurality of data bits and the first number of parity bits to a memory array as part of a first access operation. For example, the method 800 may include generating a first column select signal and writing the data to data column planes (e.g., 210 of FIG. 2, 304 of FIGS. 3-5, and/or 604 of FIGS. 6-7) and writing the first number of parity bits to an ECC column plane (e.g., 212 of FIG. 2, 306 of FIGS. 3-5, and/or 606 of FIGS. 6-7). The data and the first number of parity bits may be written to memory cells along a same word line.

Box 830 may generally be followed by box 840, which describes writing the second of number of parity bits to the memory array as part of a second access operation. For example, the method 800 may include generating a second column select signal and performing a read/modify/write RMW operation as the second access operation. The method 800 may include reading a codeword of additional information from memory cells along the word line (the same one used in box 830) specified by the second column select signal. The method 800 may include modifying the codeword of additional information to include the second number of parity bits and writing the modified codeword back to the array.

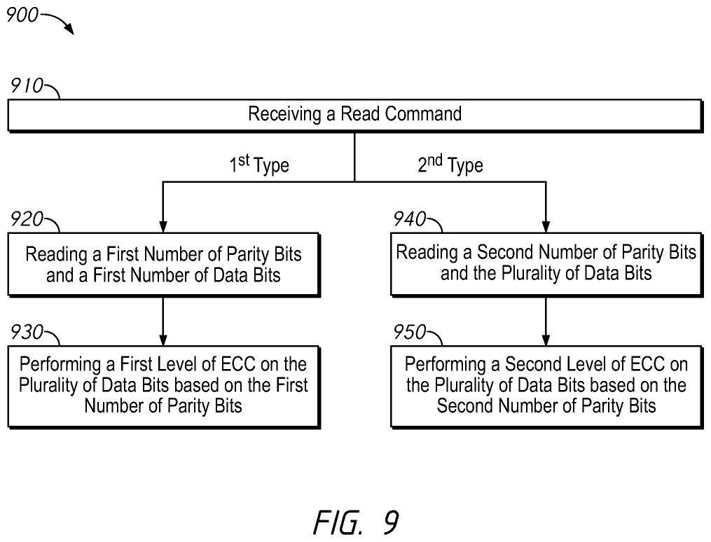

FIG. 9 is a flow chart of a method of performing a read operation according to some embodiments of the present disclosure. The method 900 may, in some embodiments, be implemented by one or more of the apparatuses or systems described herein. For example, the method 900 may be implemented by the memory device 100 of FIG. 1, 200 of FIG. 2, 300 of FIGS. 3-5 and/or 600 of FIGS. 6-7. In some embodiments, the method 900 may be used to read the same data which was written using the method 800 of FIG. 8.

The method 900 may generally begin with box 910, which describes receiving a read command, for example from a controller (e.g., 150 of FIG. 1). The method 900 may include determining if the read command is a first type of read command or a second type of read command. For example, a bit of the read command may indicate the type of read command. The method 900 may also include receiving a row and column address along with the read command

If the read command is the first type of read command, then the method 900 may proceed with box 920, which describes reading a first number of parity bits and a plurality of data bits. The first number of parity bits and the plurality of data bits may be read as part of a single access pass (e.g., as shown in FIG. 4). The method 900 may include generating a first column select signal and activating a word line and reading the data bits from memory cells in data column planes and reading the parity bits from an ECC column plane.

Box 920 may generally be followed by box 930, which describes performing a first level of ECC on the plurality of data bits based on the first number of parity bits. For example, the first level may be SEC.

If the read command is the second type of read command, then the method 900 may proceed from box 910 to box 940, which describes reading a second number of parity bits and the plurality of data bits. The second number may generally be larger than the first number. In some embodiments, the first number of parity bits may represent a subset of the second number (e.g., as in the embodiments of FIGS. 3-5). In some embodiments, the second number may be separate from the first number of parity bits (e.g., as in the embodiments of FIGS. 6-7). The method 900 may include performing two access passes to read the data and the second number of parity bits. For example, in some embodiments, the method 900 may include performing a first access pass to read a first portion of the second number of parity bits and performing a second access pass to read a second portion of the second number of parity bits and the data bits. In some embodiments, the method 900 may include performing a first access pass to read the second number of parity bits and performing a second access pass to read the data bits. The first access pass may retrieve a codeword of additional information and the method 900 may include extracting the second number of parity bits (or a portion thereof) from the codeword of additional information. The method 900 may include generating a first column select signal for the data (and if applicable a second portion of the parity bits) and generating second column select signal for the codeword of additional information.

Box 940 may generally be followed by box 950 which describes performing a second level of ECC on the plurality of data bits based on the second number of parity bits. The second level may involve detecting/correcting more bits than the first level described in box 930. For example, the box 950 may include performing SECDED, DEC, TEC, or other levels of ECC.

In some embodiments, the correction described in box 930 may be performed by a first ECC engine (e.g., 611 of FIGS. 6-7) and the second level of ECC described in box 950 may be performed by a second ECC engine (e.g., 613 of FIGS. 6-7).

The method 900 may include providing an error signal (e.g., ErrDet of FIG. 1), either directly or indirectly, responsive to detecting or correcting an error in the plurality of data bits (e.g., either in box 930 or box 950).

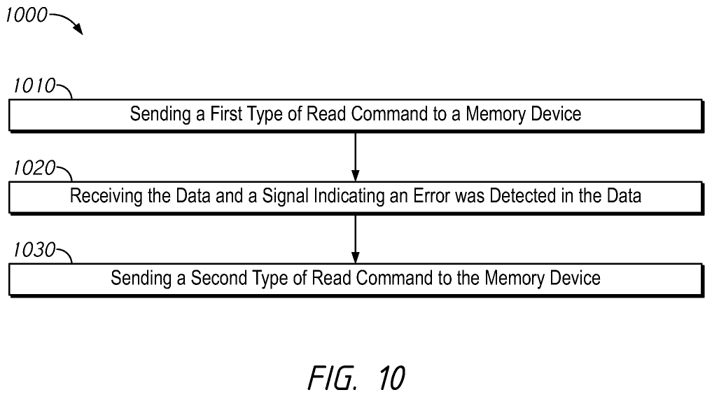

FIG. 10 is a method of reading data from a memory device according to some embodiments of the present disclosure. The method 1000 may, in some embodiments, be performed by a controller such as the controller 150 of FIG. 1.

The method 1000 includes box 1010 which describes sending a first type of read command to a memory device. For example, the method 1000 may include providing the first type of read command along with a row and column addresses along a CA bus that couples the controller to the memory.

Box 1010 is followed by box 1020, which describes receiving data and a signal indicating an error was detecting in the data. For example, the data may be received along DQ terminals and a DQ bus between the memory and the controller. In some embodiments, the error detected signal (e.g., ErrDet of FIG. 1) may be received directly (e.g., along a sideband channel). In some embodiments, the error detected signal may be received indirectly. For example, the method 1000 may include receiving an alert signal from the memory and performing a mode register read operation to retrieve the error detected signal.

If an error was detected, the method 1000 may include box 1030, which describes sending a second type of read command to the memory device. For example, the box 1030 may include providing the same row and column address as were provided in the box 1010, but along with the second type of read command. The method 1000 may include receiving the data and a signal indicating if an error was detected, similar to box 1020.

The method 1000 may include the read operations described with respect to FIG. 9. The memory may perform a second level of ECC responsive to the second type of read operation which is higher than the first level of ECC performed responsive to the first type of read operation.

Of course, it is to be appreciated that any one of the examples, embodiments or processes described herein may be combined with one or more other examples, embodiments and/or processes or be separated and/or performed amongst separate devices or device portions in accordance with the present systems, devices and methods.

Finally, the above-discussion is intended to be merely illustrative of the present system and should not be construed as limiting the appended claims to any particular embodiment or group of embodiments. Thus, while the present system has been described in particular detail with reference to exemplary embodiments, it should also be appreciated that numerous modifications and alternative embodiments may be devised by those having ordinary skill in the art without departing from the broader and intended spirit and scope of the present system as set forth in the claims that follow. Accordingly, the specification and drawings are to be regarded in an illustrative manner and are not intended to limit the scope of the appended claims.

What is claimed is:

1. An apparatus comprising:
a memory array configured to provide data bits and a plurality of parity bits responsive to a first type of read command or a second type of read command, wherein the memory array provides a first number of the plurality of parity bits responsive to the first type of read command or a second number of the plurality of parity bits greater than the first number responsive to the second type of read command;
an error correction code (ECC) circuit configured to correct one or more errors in the data bits based on the plurality of parity bits.

2. The apparatus of claim 1, wherein responsive to the first type of read command the ECC circuit is configured to correct one bit of error in the data, and wherein responsive to the second type of read command the ECC circuit is configured to detect and/or correct more than one bit of error in the data.

3. The apparatus of claim 1, further comprising:
a column decoder configured to provide a first column select signal responsive to the first type of read command and configured to provide the first column select signal and a second column select signal responsive to the second type of read command.

4. The apparatus of claim 1, wherein responsive to the first type of read command the data and the plurality of parity bits are read as part of a single access pass of the memory array and responsive to the second type of read command the data and the plurality of parity bits are read as part of two access passes of the memory array.

5. The apparatus of claim 4, wherein responsive to the second type of read command a portion of the plurality of parity bits is read as part of a first access pass and a remainder of the plurality of parity bits and the data is read as part of a second access pass.

6. The apparatus of claim 4, wherein responsive to the second type of read command the plurality of parity bits is read as part of a first access pass and the data is read as part of a second access pass.

7. The apparatus of claim 1, wherein the ECC circuit is configured to provide an error detected signal responsive to correcting the one or more errors and wherein a controller is configured to provide the second type of read command responsive to the error detected signal.

8. A system comprising:
a controller configured to provide a first type of read command or a second type of read command; and
a memory device comprising:
a memory array configured to provide data and parity bits responsive to the first type of read command or the second type of read command wherein there is a first number of parity bits responsive to the first type of read command and a second number of parity bits responsive to the second type of read command; and
an error correction code (ECC) circuit configured to perform a first level of error correction on the data responsive to the first type of read command and to perform a second level of error correction on the data responsive to the second type of read command, wherein more errors are detected or corrected in the second level of error correction than in the first.

9. The system of claim 8, wherein the memory is configured to provide an error detected signal if an error is detected or corrected by the ECC circuit, and wherein the controller is configured to provide the second type of read command responsive to the error detected signal.

10. The system of claim 8, wherein the controller is configured to provide the data along with a write command, and wherein the ECC circuit is configured to generate the parity bits based on the data.

11. The system of claim 10, wherein the ECC circuit is configured to generate the second number of parity bits responsive to the write command, and wherein the first number of the parity bits represents a portion of the second number of parity bits.

12. The system of claim 10, wherein the ECC circuit comprises:
a first ECC engine configured to provide the first number of parity bits responsive to the write command; and
a second ECC engine configured to provide the second number of parity bits responsive to the write command,
wherein the first number of parity bits are read responsive to the first type of read command and the second number of parity bits are read responsive to the second type of read command.

13. The system of claim 8, wherein the first level of error correction is single error correction (SEC).

14. The system of claim 8, wherein the memory further comprises a column decoder configured to perform a single access pass on the memory array responsive to the first type of read command and to perform two access passes on the memory array responsive to the second type of read command.

15. A method comprising:
receiving a read command which is a first type of read command or a second type of read command;
reading a first number of parity bits and a plurality of data bits responsive to the first type of read command;
performing a first level of error correction on the plurality of data bits based on the first number of parity bits;
reading a second number of parity bits and the plurality of data bits responsive to the second type of read command; and
performing a second level of error correction on the plurality of data bits based on the second number of parity bits.

16. The method of claim 15, further comprising:
sending the first type of read command from a controller to a memory;
receiving the plurality of data bits and a signal indicating that an error was detected in the plurality of data bits from the memory; and
sending the second type of read command from the controller to the memory responsive to the signal.

17. The method of claim 16, further comprising sending the first type of read command and the second type of read command along with a same row address and column address.

18. The method of claim 15, wherein the second level is greater than the first level.

19. The method of claim 18, further comprising:
performing single error correction as the first level of error correction; and
performing single error correction double error detection, double error correction, or triple error correction as the second level of error correction.

20. The method of claim 15, further comprising:
receiving a write command and the plurality of data bits;
generating the first number of parity bits and the second number of parity bits based on the data bits;
writing the plurality of data bits and the first number of parity bits as part of a first access operation; and
writing the second plurality of parity bits as part of a second access operation.
